(19) United States
(12) Patent Application Publication
(10) Pub. No.: US 2002/0095273 A1
(43) Pub. Date: Jul. 18, 2002

(54) Method of extracting physical model parameter and storage medium therefor, and method of manufacturing non-linear element

(75) Inventor: Motoaki Tanizawa, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Chiyoda-ku (JP)

(21) Appl. No.: 09/850,236

(22) Filed: May 8, 2001

(30) Foreign Application Priority Data
Nov. 27, 2000 (JP) 2000-359113

(51) Int. Cl. H03F 1/26; G06F 15/00; H04B 15/00

(52) U.S. Cl. 702/189

(57) ABSTRACT

An error function S is defined by dividing the square of the difference between each of the characteristic quantities σ_{iy} and corresponding the function f_{y} (vᵢ, P) by variance σ_{iy}² of observed values from a plurality of samples and summing the quotients for the plural number of extrinsic factor sets. It is possible to correct the effects of variation and bias of the observed values included in the error factor with division by the variance σiy² for each of the characteristic quantities even when there is a variation in size among the values of the error factors in the characteristic quantities. Further, it is verified whether the function f_{y} (vₛ, P) reproduces the observed values by utilizing conformity of the value of the error function S to χ² distribution and when it is verified that the function f_{y} (vₛ, P) reproduces the observed values, the parameter set P at that time is extracted as one that gives the minimum value of the error function S. Thus provided is a method of extracting physical model parameters which allows sufficient reduction in value of the error factor for each characteristic quantity even when there is a variation in size among the values of the error factors in the characteristic quantities in the error function, and a technique for a quick parameter extraction to obtain a true solution can be achieved.

### BACKGROUND OF THE INVENTION

1. Field of the Invention

The present invention relates to physical properties that provide characteristic quantity sets gᵢ (i=1, 2, . . . , m) each consisting at least one characteristic quantity, corresponding to a plurality of extrinsic factor sets vᵢ, respectively, each consisting of at least one extrinsic factor, more particularly to a technique for extracting a parameter set P in a physical model for expressing a calculated value of each characteristic quantity set gₛ (s is any one value of i) as a function f (vₛ, P) of the corresponding extrinsic factor vₛ and the parameter set P consisting of a plurality of parameters.

One example is a technique for extracting model parameters for use in a circuit simulation in LSI (Large Scale Integrated circuit) designs.

2. Description of the Background Art

A process of manufacturing an LSI is broadly divided into a design step for designing circuits thereof and a semiconductor processing step for implementing the circuits as a semiconductor device form according to information obtained in the design step. In the design step, a circuit simulation is performed to predict the functions of an LSI circuit as a semiconductor device (hereinafter referred to as “LSI devices”).

We can look at the circuit simulation from two important viewpoints: formulation of circuit equations and device modeling. In the device modeling, electric properties of a non-linear device such as a transistor are simulated by using an analytic formula obtained by modeling the device. The analytic formula includes physical or semi-empirically-determined parameters.

To perform the circuit simulation with high precision, the parameters for use in the device modeling need to be determined properly. As an index to this determination, errors between measured characteristics of the LSI device and calculated values on the basis of an analytical model are usually adopted. Alternatively, instead of the measured characteristics of the LSI device, results of device simulation for simulating phenomena which occur in a device such as a transistor can be used.

Discussion will be now on a background-art method of extracting physical model parameters. The physical model is set to obtain the physical properties of a non-linear element, where a non-linear relation is established between extrinsic factor sets vᵢ (i=1, 2, 3, . . . , m) each consisting of at least one extrinsic factor and characteristic quantity sets gᵢ obtained correspondingly to the extrinsic factor sets vᵢ, respectively, each consisting of at least one characteristic quantity. The physical model is expressed as a function f (vᵢ, P) of the extrinsic factor set vᵢ and a parameter set P consisting of a plurality of parameters. An error function S is obtained by multiplying a difference between a measured characteristic quantity set gₛ (s is any one number of i) and a calculated function f (vᵢ, P) by a weighting function wₛ and then summing the squares of the products for all extrinsic factor sets vᵢ. Then, a combination of parameters that minimizes the value of the error function S is extracted.

Taking an MIS transistor as an exemplary non-linear element, when the gate length is longer than about 1 μm, for example, a Frohman-Bentchkowsky model can be used as a physical model. Examples of the extrinsic factors include an operating temperature τ and potentials of a gate electrode (gate voltage V_{gs}) and a drain electrode (drain voltage V_{ds}) with respect to a source electrode. Examples of the characteristic quantities include a current (drain current I_{ds}) flowing between the source electrode and the drain electrode and conductance ∂I_{ds}, ∂V_{ds} obtained by differentiating the drain current I_{ds} by the drain voltage V_{ds}. Examples of the parameters include a threshold voltage Vₜₕ and a factor β as described later. Thus, the number of extrinsic factors constituting the extrinsic factor set, the number of characteristic quantities constituting the characteristic quantity set, and the number of parameters constituting the parameter set do not generally agree with one another.

In the operation of the MIS transistor, for example, the drain current I_{ds} in a linear region with a small drain voltage V_{ds} is obtained by approximately β(V_{gs}−Vₜₕ−V_{ds}/2)V_{ds}. The factor β is a value obtained by dividing a product of the capacitance Cₒₓ of gate insulating film per unit area, the mobility μ of carriers, and the channel width W by the channel length L (β=CₒₓμW/L). Based on such a model, the dependency of the drain current I_{ds} on the gate voltage V_{gs} is obtained from the measured values, and the threshold voltage Vₜₕ and the factor β are obtained by calculating extrapolation and gradients.

The error function S of the MIS transistor as an example of a non-linear element is expressed by the following equation (1):

$$S = {\sum }_{i = 1}^{m} {\{ {g}_{i} - f ( {v}_{i} , P ) \}}^{2} {w}_{i}^{2} \qquad ( 1 )$$

Each of the extrinsic factor sets v₁, V₂, V₃, . . . , vₘ consists of x (≧1) extrinsic factors. When x=3, for example, the operating temperature τ, the gate voltage V_{gs}, and the drain voltage V_{ds} can be adopted as extrinsic factors.

The characteristic quantity set gᵢ is a physical quantity of the non-linear element with the extrinsic factor set vᵢ. The drain current I_{ds} and the conductance ∂I_{ds}/∂V_{ds} can be adopted as characteristic quantities, for example; and in this case, the number of characteristic quantities constituting a characteristic quantity set is two and all of gᵢ, f (v_{i,} P) and wᵢ are vector quantities. Since the calculation of the equation (1) is carried out for each factor of the vectors, however, the error function S corresponds to the scalar quantity.

Further, as characteristic quantities, device simulation results can be used instead of measured values. In such a case, generally, a characteristic quantity set can be also expressed generally as gᵢ=g(vᵢ), where g is a function approximating devices by device simulation.

The parameter set P consists of n(≧2) parameters p₁, p₂, p₃, . . . pₙ. When n=2, for example, the threshold voltage Vₜₕ and the factor β can be adopted as parameters.

The weighting functions wᵢ are set correspondingly to the extrinsic factor sets vᵢ, respectively. By way of exception, the weighting functions wᵢ can be set to a constant 1 for any of the extrinsic factor sets vᵢ and the error function S can be defined as an absolute error. Further, when Wᵢ=1/gᵢ, the error function S is defined as a relative error.

Parameter extraction is such an operation as above to obtain a parameter set P that minimizes the error function S or reduces it to zero within a predetermined error limit. The extraction operation proceeds by reducing the value of the error function S while updating the parameter set P using a predetermined rule.

To find a combination of parameters that minimizes the value of the error function S, a descending method such as Newton's method (in the present specification, referred to as “Newton-based solution”) and a global search algorithm such as Simulated Annealing method (in the present specification, referred to as “combinatorial optimization method ”) have been conventionally adopted.

The above background-art methods of extracting physical model parameters, however, have the following problems.

The first problem is as follows: in searching the minimum value of the error function S by using the Newton-based solution or the combinatorial optimization method with a characteristic quantity set gᵢ consisting of a plurality of characteristic quantities, when there is a variation in size among the values of the errors (referred to as “error factors”) of the characteristic quantities, with respect to a characteristic quantity whose error factor has a large value, the error factor can be effectively reduced but with respect to a characteristic quantity whose error factor has a small value, the error factor can not be effectively reduced.

In the case, such as the above MIS transistor, where the drain current I_{ds} and the conductance ∂I_{ds}/∂V_{ds} are adopted as the characteristic quantities constituting the characteristic quantity set g₁, respective error factors of these characteristic quantities are obtained and the search of the minimum value of the error function S is performed by multiplying the sum of the squares of these error factors by the weighting function. Since the error value in the conductance ∂I_{ds}/∂V_{ds} is larger than that in the drain current I_{ds} as discussed later in detail, however, the calculation proceeds in a tendency to reduce the error factor in the conductance ∂I_{ds}/∂V_{ds} more than that in the drain current I_{ds}. As a result, the accuracy in fitting of the drain current I_{ds} becomes lower than that in the case where the drain current I_{ds} is adopted alone as the characteristic quantity.

The drain current I_{ds} in a linear region is obtained by approximately β(V_{gs}−Vₜₕ−V_{ds}/2)V_{ds} as discussed earlier. In a saturation region (where V_{ds}>V_{dsat}: V_{dsat} is a value of drain voltage V_{ds} at the time when the drain current I_{ds} starts not increasing even as the drain voltage V_{ds} increases), however, the drain voltage V_{ds} in the above formula is replaced by V_{dsat} and further the channel length L in the factor β is replaced by (L−ΔL) (ΔL represents a spread width of a depletion layer at a drain end) in consideration of channel length modulation effect. Furthermore, ΔL is a function of (V_{ds}−V_{dsat}).

In this case, though the drain current I_{ds} depends on ΔL, the conductance which is obtained by differentiating the drain current I_{ds} by the drain voltage V_{ds} depends on not only ΔL but also ∂ΔL/∂V_{ds}. Though it is possible to express the behavior of the ΔL relative to the variation in (V_{ds}−V_{dsat}) with high accuracy from depletion approximation, it is likely to cause a problem in accuracy of expression for ∂ΔL/∂V_{ds} especially near V_{ds}=V_{dst}. Therefore, the accuracy of the conductance which includes ∂ΔL/∂V_{ds} as a parameter is lower than that of the drain current I_{ds} which is not affected by that term.

Specifically, since the model formula in the MIS transistor is set by connecting the formulae of the drain currents in the operating regions (weak inversion region, strong inversion/linear region, strong inversion/saturation region), it is likely to cause deterioration in accuracy of the value of conductance which is obtained by differentiating the drain current by the drain voltage, especially near the connections of the regions. Therefore, the value of error factor in the conductance ∂I_{ds}/∂V_{ds} is likely to becomes larger than that in the drain current I_{ds}. As a result, when fittings of these error factors are performed simultaneously, there is a tendency to reduce the error factor in the conductance ∂I_{ds}/∂V_{ds} more than that in the drain current I_{ds}.

On the other hand, the second problem in the background-art method of extracting physical model parameters is as follows: when the combinatorial optimization method is used in searching the minimum value of the error function S, its computational expenses for reaching a true minimum value disadvantageously become enormous, though it is possible to avoid entrapment in local solutions. Further, use of the Newton-based solution causes entrapment in local solutions.

### SUMMARY OF THE INVENTION

The present invention is directed to a method of extracting physical model parameters. According to a first aspect of the present invention, the method of extracting physical model parameters comprises the steps of: (a) adopting a physical model for physical properties that provide characteristic quantity sets gᵢ (i=1, 2, . . . , m) each consisting of the first to z-th (z≧2) characteristic quantities g_{iy} (y=1, 2, . . . , z), corresponding to a plurality of extrinsic factor sets vᵢ, respectively, each of which consists of at least one extrinsic factor, the physical model expressing a calculated value of each characteristic quantity set gₛ (s is any one value of i) as a function f_{y} (vᵢ, P) of corresponding one extrinsic factor set vₛ and a parameter set P consisting of a plurality of parameters; and (b) obtaining an error function S by summing values each of which are obtained by dividing the square of the difference between each of the characteristic quantities g_{iy} and corresponding function f_{y} (vᵢ, P) by variance σ_{iy}² of observed values of the characteristic quantities giy obtained by observing the physical properties of a plurality of samples, for the plural number of extrinsic factor sets and extracting the parameter set P that gives the minimum value of the error function S.

According to a second aspect of the present invention, in the method of extracting physical model parameters of the first aspect, the step (b) is the step of: (b-a) extracting the parameter set P that gives the minimum value of the error function S by obtaining the error function S repeatedly with the parameter set P updated, and the step (b) includes the step of: (b-1) verifying if the function f_{y} (vₛ, P) obtained by calculation using updated parameter set P reproduces the observed values of each characteristic quantity set gₛ obtained from the plurality of samples by utilizing conformity of the value of the error function S to/distribution and extracting the parameter set P at that time as one that gives the minimum value of the error function S when the function f_{y} (vₛ, P) reproduces the observed values.

Preferably, the step (b) is the step of: obtaining the error function S repeatedly with the parameter set P updated while maintaining a probability Q of increasing the value of the error function S positive.

Preferably, the probability Q is obtained on the basis of a predetermined amount which fluctuates monotonously as the parameter set P is updated, and the predetermined amount contributes to a tendency to decrease the probability Q as the parameter set P is updated.

Preferably, the step (b) is the step of: updating the parameter set P only in such a direction that the error function S decreases monotonously.

Preferably, Gauss-Newton method is adopted in the step (b).

Preferably, Levenberg-Marquardt method is adopted in the step (b).

According to a third aspect of the present invention, in the method of extracting physical model parameters of the second aspect, the step (b) further includes the steps of: (b-2) judging if the value of the error function S obtained with the parameter set P updated is considered as the minimum value when the function f_{y} (vₛ, P) does not reproduce the observed values of the characteristic quantity set gₛ obtained from the plurality of samples in the step (b-1) and extracting the parameter set P at that time as one that gives the minimum value of the error function S when the value of the error function S is considered as the minimum value; and (b-3) judging if the number of updates exceeds a predetermined number of times when the value of the error function S is not considered as the minimum value in the step (b-2) and extracting the parameter set P at that time as one that gives the minimum value of the error function S when the number of updates exceeds the predetermined number of times or obtaining the value of the error function S with the parameter set P updated to go back to the step (b-1) when the number of updates does not exceed said predetermined number of times.

According to a fourth aspect of the present invention, in the method of extracting physical model parameters of the third aspect, the method used in the step (b-a) of extracting the parameter set P that gives the minimum value of the error function S is changed to execute the steps (b-1) to (b-3) again, instead of extracting the parameter set P at that time as one that gives the minimum value of the error function S, when it is judged that the number of updates exceeds the predetermined number of times in the step (b-3).

The present invention is also directed to a computer-readable storage medium. According to a fifth aspect of the present invention, the computer-readable storage medium stores a program that causes a computer to execute the method of extracting physical model parameters as defined in any one of the first to fourth aspects independently or in combination with a program previously stored in the computer.

The present invention is still directed to a method of manufacturing a non-linear element. According to a sixth aspect of the present invention, the method of manufacturing a non-linear element manufactures a non-linear element by performing: a characteristic simulation which adopts device modeling using the method of extracting physical model parameters as defined in any one of the first to fourth aspects; and a physical process on the basis of the characteristic simulation.

In the method of extracting physical model parameters of the first aspect, since the error function S is obtained by summing values each of which are obtained by dividing the square of the difference between each of the characteristic quantities g_{iy} and corresponding function f_{y} (vᵢ, P) by variance σ_{iy}² of observed values from a plurality of samples for the plural number of extrinsic factor sets in the step (b), it is possible to correct the effects of variation and bias of the observed values included in the error factor with division by the variance σ_{iy}² for each of the characteristic quantities even when there is a variation in size among the values of the error factors in the characteristic quantities in the error function S. Therefore, the error function S becomes a function normalized on each characteristic quantity, and that prevents a strong effect on the error function S by biased error factor of a specified characteristic quantity and provides the method of extracting physical model parameters which allows sufficient reduction in error value for each characteristic quantity.

In the method of extracting physical model parameters of the second aspect, since it is verified whether the function f_{y} (vᵢ, P) reproduces the observed values of each characteristic quantity set gₛ by utilizing conformity of the value of the error function S to χ² distribution in the step (b-1) and the parameter set P at that time is extracted as one that gives the minimum value of the error function S when it is verified that the function f_{y} (vₛ, P) reproduces the observed values, it is not necessary to repeat the calculation until the value of error function S converges to be considered as minimum and therefore an efficient and quick extraction of the parameter set P can be achieved.

In the method of extracting physical model parameters of the third aspect, since the step (b) includes the step (b-2) of judging if the value of the error function S obtained with the parameter set P updated in the step (b-1) is considered as the minimum value and the step (b-3) of judging if the number of updates exceeds a predetermined number of times, a subsidiary extraction of the parameter set P can be achieved even when it is verified that the function f_{y} (vₛ, P) does not reproduce the observed values.

In the method of extracting physical model parameters of the fourth aspect, when it is judged that the number of updates exceeds the predetermined number of times in the step (b-3), the method used in the step (b-a) is changed to execute the steps (b-1) to (b-3) again, instead of extracting the parameter set P at that time as one that gives the minimum value of the error function S. Therefore, it becomes possible to adopt one of the combinatorial optimization method and the Newton-based solution first in the step (b-a) and adopt the other one in the step (b-a) to retry the extraction of the parameter set P when the first method fails the extraction of the parameter set P.

In the computer-readable storage medium of the fifth aspect, it is possible to cause a computer to execute the method of extracting physical model parameters as defined in any one of the first to fourth aspects.

In the method of manufacturing a non-linear element of the sixth aspect, since the physical process are carried out on the basis of the characteristic simulation with high accuracy at low computational cost, the non-linear element can be manufactured, being close to a design specification, at low cost.

An object of the present invention is to provide a method of extracting physical model parameters, which allows sufficient reduction in value of an error factor for each characteristic quantity even if there is a variation in size among the values of the error factors of the characteristic quantities in the error function, and further provide a technique to perform an efficient and quick parameter search, i.e., parameter extraction for obtaining a true solution.

Another object of the present invention is to provide a storage medium for storing a computer-driven program to extract parameters.

Still another object of the present invention is to provide a method of manufacturing a non-linear element, which includes physical simulations using the parameter extraction technique.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart showing an overview of manufacturing process of an LSI device in accordance with the present invention;

FIG. 2 is a flowchart showing an operation of a parameter extractor in accordance with the present invention;

FIG. 3 is a flowchart showing a method of extracting physical model parameters in accordance with a first preferred embodiment of the present invention;

FIG. 4 is a flowchart showing a Newton-based solution;

FIG. 5 is a flowchart showing a method of extracting physical model parameters in accordance with a second preferred embodiment of the present invention; and

FIGS. 6 and 7 are flowcharts showing a method of extracting physical model parameters in accordance with a third preferred embodiment of the present invention.

### DESCRIPTION OF THE PREFERRED EMBODIMENTS

<The First Preferred Embodiment>

A. Basic Idea:

The first preferred embodiment shows a method of extracting physical model parameters, which allows sufficient reduction in value of an error factor for each characteristic quantity even if there is a variation in size among the values of the error factors of the characteristic quantities in the error function.

Prior to giving a detailed description of the first preferred embodiment, we will describe a basic idea of the present invention. Also in the first preferred embodiment, like in the background-art technique, the physical model is set as the physical properties of a non-linear element, where a non-linear relation is established between extrinsic factor sets vᵢ (i=1, 2, 3, . . . , m) each consisting of at least one extrinsic factor and corresponding characteristic quantity sets gᵢ each consisting of at least one characteristic quantity. The physical model is expressed as a function f (vᵢ, P) of the extrinsic factor set vᵢ and a parameter set P consisting of a plurality of parameters. Further, an error function S is obtained on the basis of this physical model.

In the first preferred embodiment, however, the sum of values obtained by dividing the squares of the error factors which are obtained by observation or calculation in device simulation of the properties of u (u≧2) prototypes by variances of observed values of corresponding characteristic quantities for the plural number of extrinsic factor sets (e.g., total number m) is adopted as the error function S of the physical model.

Then, a combination of parameters that minimizes the value of the error function S is extracted.

The present invention is not to be restricted to the application to the semiconductor field but is also applicable to other fields such as electricity, machinery, and chemistry if it is the technique for adopting a physical model expressed as a function containing parameters as above described. The following discussion will be made, taking a field of method of manufacturing semiconductor devices as an example.

B. Application to Method of Manufacturing Semiconductor Device:

b1) Overview of Method of Manufacturing Semiconductor Device.

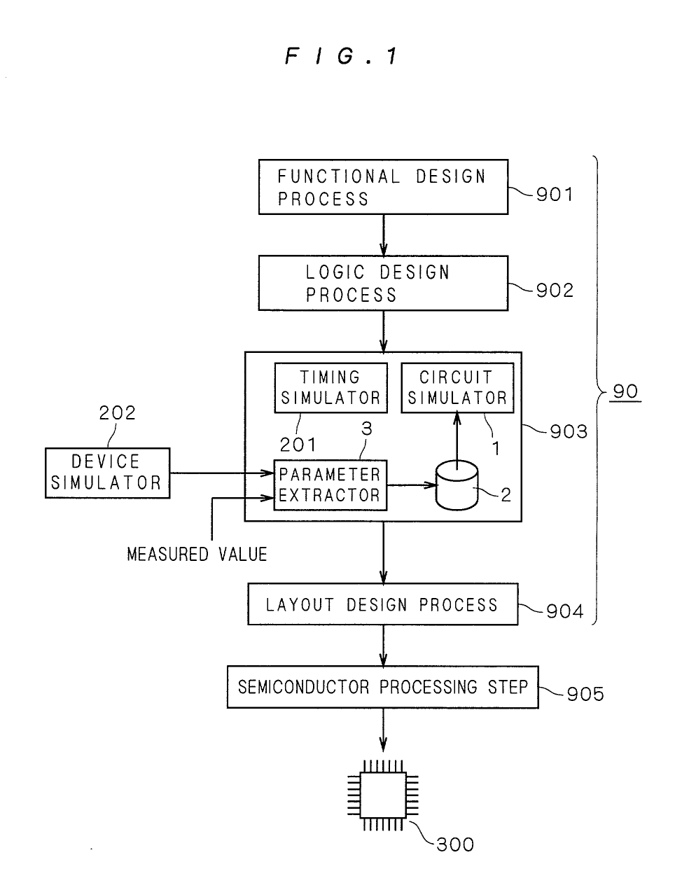

FIG. 1 is a flowchart showing an overview of the manufacturing process of an LSI device to which the present invention is applicable. The manufacturing process is broadly divided into a design process group 90 and a semiconductor processing step 905 which is a physical process. The design process group 90 is broadly divided into a functional design process 901, a logic design process 902, a circuit design process 903, and a layout design process 904. In the semiconductor processing step 905, a semiconductor processing is performed on the basis of information from the design process group 90, and an LSI device 300 is thereby obtained.

The execution of the circuit design process 903 is carried out by a circuit simulator 1 and a parameter extractor 3. In addition, a timing simulator 201 may be adopted. The circuit simulator 1 is a main device for performing circuit simulations, and the parameter extractor 3, which supplies parameters to the circuit simulator 1, receives measured values of the manufactured LSI device 300 and simulation results from a device simulator 202. The circuit design process 903 may also adopt a parameter database 2 for storing parameters determined by the parameter extractor 3. In the example of FIG. 1, the circuit design process 903 adopts the circuit simulator 1, the parameter database 2, the parameter extractor 3, and the timing simulator 201, all of which are enclosed by a box indicating the circuit design process 903.

FIG. 1 is merely one example in schematic form; so the process steps 901 to 904 in the design process group 90 need not be independent of one another and the parameter extractor 3 needs not be individual hardware. For example, the whole design process group 90 may be implemented by a single computer operating on the basis of a predetermined program. It is, of course, possible to operate the parameter extractor 3 by exclusive software or by a patch program for existing software to operate the whole design process group 90. Such software and program can be stored in a computer-readable storage medium.

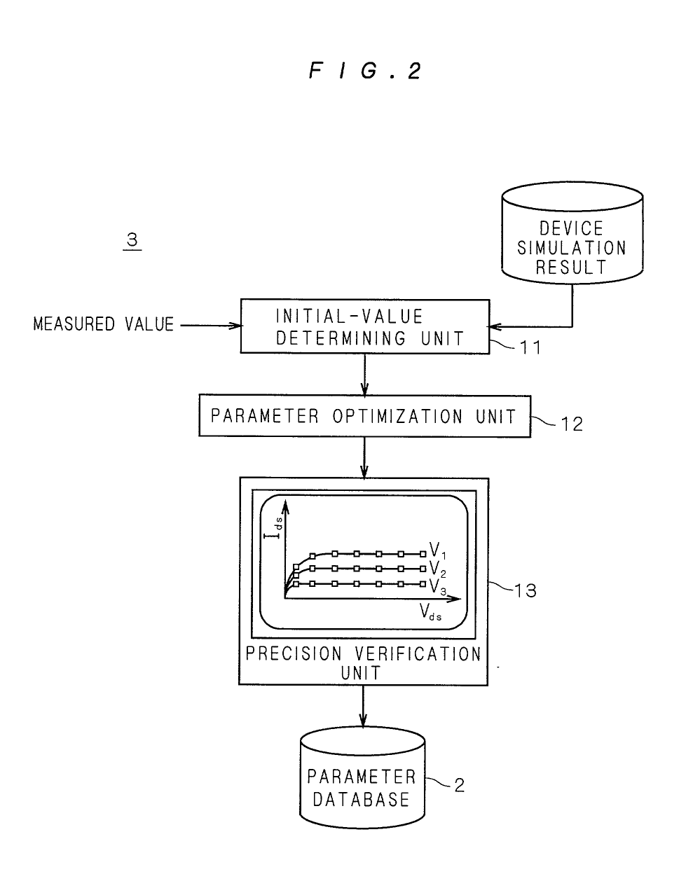

FIG. 2 is a flowchart showing an operation of the parameter extractor 3 in accordance with the present invention. First, measured values obtained by measuring equipment such as a parameter analyzer and an LCR meter are inputted to an initial-value determining unit 11. It is preferable that the measuring equipment should operate under automatic control. Alternatively, device simulation results obtained by the device simulator 202 may be inputted.

To determine parameters in device modeling, repeated calculations are usually performed. For efficient repeated calculations, the initial-value determining unit 11 determines initial values of such parameters. A proper selection of these initial values is deeply involved in the precision of parameters to be finally obtained. For this reason, the initial-value determining unit 11 adopts a simple model which restricts the operating range and shape of devices to explicitly determine the initial values of some parameters without necessitating the repeated calculations.

In the operation of an MIS transistor, for example, the drain current I_{ds} in a linear region with a small drain voltage V_{ds} is obtained by approximately β(V_{gs}−Vₜₕ−V_{ds}/2)V_{ds}. Based on such a model, the dependency of the drain current I_{ds} on the gate voltage V_{gs} is obtained from the measured values, and the threshold voltage Vₜₕ and the factor β are obtained by calculating extrapolation and gradients.

The initial values of some parameters obtained in this way are given to a parameter optimization unit 12 together with the measured values or device simulation results, where parameters are determined. The details of an operation of the parameter optimization unit 12 will be discussed later.

Device characteristics calculated by using the parameters obtained in the parameter optimization unit 12 are displayed in a precision verification unit (display device) 13 together with those obtained from the measured values, such as the dependency of the drain current I_{ds} on the drain voltage V_{ds}. This allows visual recognition of the precision of determined parameters. In FIG. 2, the dependency of the drain current I_{ds} on the drain voltage V_{ds} is plotted at different gate voltages V₁, V₂ and V₃.

When parameters with satisfactory precision are acknowledged, the parameters are stored in the parameter database 2 for reuse.

FIG. 2 is merely one example in schematic form; so the units 11 to 13 need not be independent of one another. For example, the whole parameter extractor 3 may be implemented by a single computer operating on the basis of a predetermined program. It is, of course, possible to operate the parameter optimization unit 12 by exclusive software or by a patch program for existing software to operate the whole design process group 90. Such software and program can be stored in a computer-readable storage medium. That allows a computer to execute the method of extracting physical model parameters.

Further, when a characteristic simulation is performed by using the method of extracting physical model parameters of the first preferred embodiment and the physical process is executed on the basis of the characteristic simulation to manufacture a non-linear element such as an MIS transistor, since the physical process is executed on the basis of the characteristic simulation with a high degree of accuracy and low calculation cost, it is possible to manufacture a non-linear element close to design specifications at low cost.

b2) Overview of Parameter Extraction.

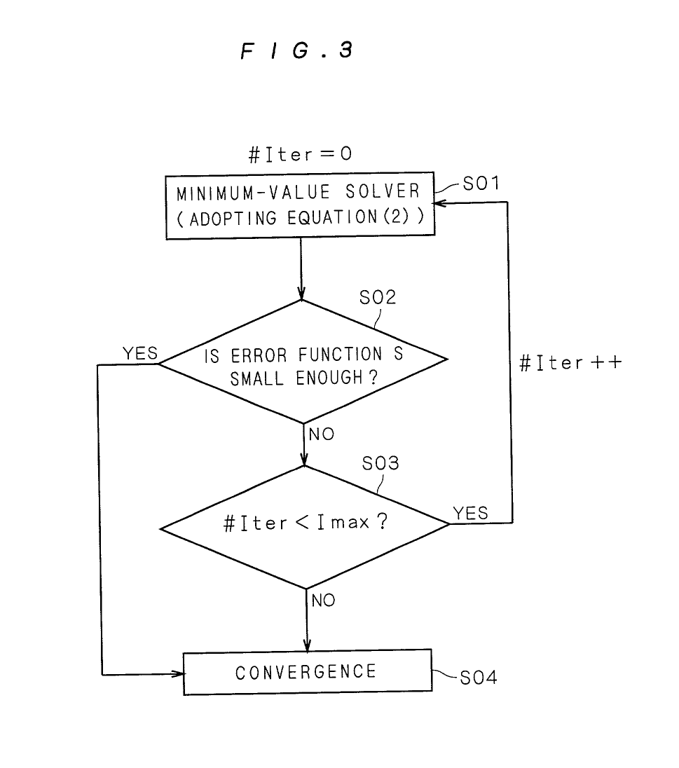

FIG. 3 is a flowchart showing an operation of the parameter optimization unit 12 in an exploded form. This flowchart shows a step of extracting the parameter set P that gives the minimum value of the error function S described in the section A.

In the step S01, a parameter search is performed by a minimum-value solver such as the combinatorial optimization method or the Newton-based solution. Herein, the minimum-value solver refers to a solution for extracting the parameter set P that gives the minimum value of the error function S by obtaining the error function S repeatedly with the parameter sets P updated. As an example of the minimum-value solver, the combinatorial optimization method will be discussed in the section b3) and the Newton-based solution will be discussed in the section b4) in detail.

Then, in the step S02, a judgment is made on whether the value of the error function S is considered as the minimum value or not. The judgment may be performed according to a convergence condition for each minimum-value solver. When it is judged that the value of the error function S is sufficiently small, considering that the error function S converges, the parameter set P at that time is extracted as one that gives the minimum value of the error function S (step S04).

On the other hand, when the value of the error function S is not considered as the minimum value, a judgment is made in the step S03 on whether the number of updates of the parameter set P, #Iter (its initial value is 0), exceeds a predetermined number of times Imax or not. When #Iter exceeds Imax, considering that the error function S converges, the parameter set P at that time is extracted as one that gives the minimum value of the error function S. On the other hand, when #Iter does not exceed Imax, the process returns to the step S01 and the error function S is obtained again with the parameter set P updated by using the minimum-value solver.

Further, “#Iter++” in the flowchart of FIG. 3 represents increment of the number of updates #Iter.

In the first preferred embodiment, as discussed in the section A, the error function S of the non-linear element such as the MIS transistor is expressed by the following equation (2):

$$S = {\sum }_{i = 1}^{m} {\sum }_{y = 1}^{z} \frac{{\{ {g}_{iy} - {f}_{y} ( {v}_{i} , P ) \}}^{2}}{{σ}_{iy}^{2}} \\ ( i = 1 , 2 , … , m ) \\ ( y = 1 , 2 , … , z ) \qquad ( 2 )$$

where the extrinsic factor set vᵢ, the characteristic quantity g_{iy}, the parameter set P and the function f_{y} (vᵢ, P) are the same as those in the background art, and the variance σ_{iy}² is a variance of the observed values of the y-th characteristic quantity in the characteristic quantity set gᵢ. Herein, the subscript y is exhibited in order to explicitly indicate that there are y (y=1, 2, . . . , z) kinds of characteristic quantities, and the equation expresses that summation for the number y is made.

The s-th (s is any one value of i) characteristic quantity set gₛ is expressed by the following equation (3):

$${g}_{s} = ( \begin{matrix}{g}_{s1} \\ ⋮ \\ {g}_{sy} \\ ⋮ \\ {g}_{sz}\end{matrix} ) , {g}_{sy} = \frac{{\sum }_{q = 1}^{u} {g}_{syq} ( {v}_{s} )}{u} \\ ( q = 1 , 2 , … , u ) \qquad ( 3 )$$

where g_{syq}(vₛ) represents an observed value of the y-th characteristic quantity of the characteristic quantity set gₛ obtained when the extrinsic factor set vₛ is given to the q-th sample and u denotes the number of samples. Taking a MIS transistor which is singly formed on a chip as an example, the observed value of the first characteristic quantity, the drain current I_{ds}, in the q-th sample out of a plurality of chips obtained by actual device manufacture or device simulation under the condition of the extrinsic factor set v_{s,} for example, corresponds to g_{s1q}(vₛ). Further, as can be understood from the equation (3), the characteristic quantity g_{sy} is an average value of the observed values g_{syq}(vₛ) of each physical property of the samples.

Furthermore, the variance σ_{sy}² of the characteristic quantity set gₛ and the variance σ_{sy}² of each characteristic quantity are expressed by the following equations (4):

$${σ}_{s}^{2} = ( \begin{matrix}{σ}_{s1}^{2} \\ ⋮ \\ {σ}_{sy}^{2} \\ ⋮ \\ {σ}_{sz}^{2}\end{matrix} ) , {g}_{sy}^{2} = \frac{{\sum }_{q = 1}^{u} {\{ {g}_{syq} ( {v}_{s} ) - {g}_{sy} \}}^{2}}{u - 1} \qquad ( 4 )$$

Herein, the variance σ_{sy}² is an unbiased estimation value. Therefore, the equation (4) is a value obtained by multiplying the sample variance by u/(u−1). Specifically, though u is used in the denominator of the equation (4), instead of (u−1), in the case of sample variance, the value obtained by multiplying the sample variance by u/(u−1) is adopted in the equation (4) in order to express the variance of the population of the samples as an unbiased estimation value.

The reason why the variance σ_{iy}² of the observed values of the characteristic quantities g_{iy} in the characteristic quantity set g₁ is introduced in the error function S is as follows.

As indicated in the equation (2), by dividing the square of error factor of each of the characteristic quantities g_{iy} by the variance σ_{iy}² of the observed values of a plurality of samples, it is possible to correct the effects of variation and bias of the observed values included in the error factor with division by the variance σ_{iy}² for each of the characteristic quantities g_{iy} even when there is a variation in size among the values of the error factors in the characteristic quantities g_{iy}. In other words, since the error function S is a function normalized on each of the characteristic quantities g_{iy}, it is possible to prevent a strong effect on the error function S by biased error factor in specific one of the characteristic quantities g_{iy}.

Therefore, it is possible to achieve the method of extracting physical model parameters, which does not cause the first problem of the background art even when there is a variation in size among the values of the error factors in the characteristic quantities and allows sufficient reduction in value of the error factor for each characteristic quantity.

Further, the process described in the steps S01 to S04 of FIG. 3 may be performed on a computer by running a program for integrally processing the steps. Alternatively, the process described in the steps S01 to S04 may be integrally performed by using hardware. The process may be carried out on a computer by running a program for executing the steps S01 to S04 separately.

Alternatively, hardware executing the steps S01 to S04 separately may be used as the parameter optimization unit 12.

b3) Combinatorial Optimization Method.

Examples of the combinatorial optimization method include well-known techniques called simulated annealing and simulated diffusion (hereinafter referred to as a “SA method” and “SD method”, respectively). The application of the SA method to semiconductor devices is discussed, for example, by Man-Kuan. Vai, et al. in an article entitled “Modeling of Microwave Semiconductor Devices Using Simulated Annealing Optimization”, IEEE Trans. Electron Devices, vol. ED-36, No. 4, pp. 761-762, April 1989 (hereinafter referred to as a “document 1”). The application of the SD method to semiconductor devices is discussed, for example, by T. Sakurai, et al. in an article entitled “Fast Simulated Diffusion: An Optimization Algorithm for Multiminimum Problems and Its Application to MOSFET Model Parameter Extraction”, IEEE Trans. Computer-Aided Design, vol. CAD-11, No. 2, pp. 228-233, February 1992 (hereinafter referred to as a “document 2”).

In the SA method and the SD method, the error function S is obtained from parameters incremented by a predetermined amount, and when the error function S is increased, the incremented parameters are adopted as updated parameters with a probability Q. In the document 1, for example, an amount for updating parameters (hereinafter referred to as the “amount of update”) is expressed as ΔV=RV₀, where V₀ is the basic amount of update and R (0≦R≦1) is a random number. The parameters updated by ΔV are used for the next calculation unless they are beyond the specified limits. In the document 2, the amount of update proportional to the gradient of the error function S is added to parameters. When the error function S obtained from resultant parameters is increased, these parameters are adopted as updated parameters with a probability Q. More specifically, when the obtained parameters increase the value of the error function S, a random number R is generated, and these parameters are adopted as updated parameters on condition that the value of random number is lower than the probability Q. When the value of the error function S decreases, on the other hand, parameter update is performed.

Both the SA method and the SD method adopt a so-called Metropolis algorithm. The Metropolis algorithm is introduced for example by R. A. Rutenbar in an article entitled “Simulated Annealing Algorithms: An Overview”, IEEE Circuits and Devices Magazine, pp. 19-25, Jan. 1989 (hereinafter referred to as a “document 3”). Referring to this algorithm along with the SA method and the SD method, a probability Q that the error function S increases by the amount of increase δS (>0) is expressed by exp(−δS/T), where 0<Q≦1 holds.

The divisor T is a predetermined amount that decreases as the calculation is repeated with an update of the parameters. In the document 1, for example, it is called a pseudo-temperature, the initial value of which is set to 500 or more and updated to 90 percent of the value as the repeated calculation is performed.

A convergence condition adopted in the SA method and the SD method is, for example, whether the magnitude of parameters is within the specified limits, whether the number of times random number generation occurs reaches a predetermined upper limit, or whether the pseudo-temperature T is cooled enough.

Additionally, as a convergence condition of the combinatorial optimization method, whether the error function S decreases a predetermined number of times in succession may be adopted.

Specifically, the combinatorial optimization method should be terminated when the error function S has decreased a predetermined number of times in succession, in which case it is judged that the error function S has decreased monotonously with each calculation carried out with the update of parameters. That is, the convergence condition can be expressed by the following equation (5):

Sₖ>Sₖ₊₁> . . . Sₖ₊ₜ (5)

where Sₖ is the value of the error function S obtained with k repeated calculations.

The number of times t that the value of the error function S has decreased in succession is, for example, set to 6. This convergence condition corresponds to the step S02 of FIG. 3. When the error function S has decreased during t repeated calculations carried out with the update of the parameter set P, the process goes to the step S04; otherwise, the process goes to the step S03.

Besides the Metropolis algorithm, the SD method further adopts the term of the Brownian movement as part of the amount of update of parameters. In the document 2, for example, the amount of update dx is expressed by the following equation (6):

dx=−∇f(x)dt+\sqrt{2T}dw (6)

In the equation (6), the parameter x and the function f are equivalent to the parameter set P and the error function S, respectively. In the right side, the first term is the drift term and the second term is equivalent to the Brownian movement. Herein, dw is the Gaussian random noise.

b4) Newton-Based Solution.

The following equation (7) should be satisfied to minimize the error function S:

$$\frac{\partial S}{\partial {p}_{j}} = 0 ( j = 1 , 2 , … , n ) \qquad ( 7 )$$

This is n-order non-linear simultaneous equations, where the parameters p₁, p₂, . . . pₙ constituting the parameter set P are unknown variables. As a technique for solving the simultaneous equations, Newton's method is the most common numerical solution, in which the parameter set P is updated after each calculation so that the error function S obtained from the updated parameter set P decreases monotonously. In this solution, the amount of update ΔP with respect to the parameter set P is calculated by using the following equation (8):

$$Δ P = {[ {J}^{T} WJ - {H}_{( k )} W ( G - F ) ]}^{- 1} {J}^{T} W ( G - F ) \\ where P = ( \begin{matrix}{p}_{1} \\ {p}_{2} \\ ⋮ \\ {p}_{n}\end{matrix} ) , G = ( \begin{matrix}{g}_{1} \\ {g}_{2} \\ ⋮ \\ {g}_{m}\end{matrix} ) , F = ( \begin{matrix}f ( {v}_{1} , P ) \\ f ( {v}_{2} , P ) \\ ⋮ \\ f ( {v}_{m} , P )\end{matrix} ) \\ {J}_{ij} = \frac{\partial }{\partial {p}_{j}} f ( {v}_{1} , P ) \\ {W}_{ij} = \{ \begin{matrix}1 / \sqrt{{σ}_{i}^{2}} ( i = j ) \\ 0 ( i \neq j )\end{matrix} \\ {H}_{( k ) ji} = \frac{{\partial }^{2} f ( {v}_{i} , P )}{\partial {p}_{j} \partial {p}_{k}} \qquad ( 8 )$$

Further, k=1, 2, . . . , n and J^{T} is the transposed matrix of J. The terms inside the square brackets indicate the Hessian of the function f (v, P).

To improve the efficiency of calculation of the amount of update ΔP, various approximation methods are applied. In the Gauss-Newton method, for example, the terms corresponding to second and higher differentiations of the function f are discarded as follows:

ΔP=[A^{T}A]⁻¹C (9)

where: A=W^{½}J, B=W^{½}(G−F), C=A^{T}B

According to the equation (9), the parameter set P is sequentially obtained by QR decomposition, e.g. by Householder method.

For further improvement in convergence, the Levenberg-Marquardt method has been proposed, wherein the diagonal terms are added as approximation of the Hessian to emphasize an element in such a direction that the error function S decreases. This technique is discussed for example by K. Dogains and D. L. Scharfetter in an article entitled “General Optimization and Extraction of IC Device Model Parameters”, IEEE Trans. Electron Devices, vol. ED-30, No. 9, pp. 1219-1228, September 1983. More specifically, the amount of update ΔP is calculated on the basis of the following equation (10):

ΔP=[A^{T}A+λD]⁻¹C (10)

where D=I+diag(A^{T}A)

where I is an unit matrix and diag() represents a matrix that adopts diagonal elements of a matrix in the parentheses as diagonal elements and zero as the other elements. The factor λ is set to a large value (e.g., approximately 0.1) at the beginning of the repeated calculations and is set to zero near the solution.

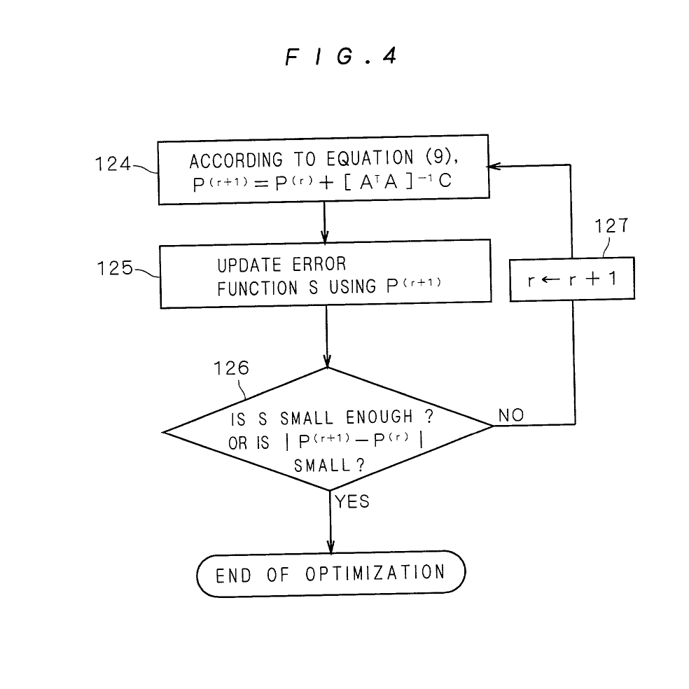

FIG. 4 is a flowchart of the Newton-based solution using the equation (9). In the step 124, the parameter set P^{(r)} obtained in the r-th calculation is increased by the amount of update {[A^{T}A]⁻¹C} to calculate a parameter set P^{(r+1)} to be obtained in the (r+1)th calculation. In the step 125, the error function S is updated using the parameter set P^{(r+1)}. In the step 126, it is determined whether the error function S is small enough, i.e., whether the error function S is zero within the specified limits. When the error function S becomes zero within the specified limits, the optimization process is terminated; otherwise, the process returns to the step 124 after the number of repetitions r is incremented by one in the step 127.

If it is judged in the step 126 that the updated parameter set P^{(r+1)} and the parameter set P^{(r)} before update are within the specified limits, the optimization process is terminated since further repetition of calculations would not improve the precision of the parameter set P. This is a convergence condition for the Newton-based solution. If they are not within the specified limits, the process returns to the step 124 through the step 127.

The steps 124 and 125 in FIG. 4 correspond to the steps S01 in FIG. 3 and the step 126 in FIG. 4 corresponds to the step S02 in FIG. 3.

C. Variation:

While the document 3 discusses the case of adopting a Boltzmann distribution to show the probability in the Metropolis algorithm, a Lorentz distribution can be adopted as discussed in the document 2. Alternatively, it is also possible to adopt a function which discards terms of higher order than a term of a predetermined order in a series obtained by expanding the Boltzmann distribution.

<The Second Preferred Embodiment>

The second predetermined embodiment is a variation of the method of extracting physical model parameters in accordance with the first preferred embodiment, and is a method of extracting physical model parameters which allows an efficient and quick parameter extraction as well as sufficient reduction in value of an error function for each characteristic quantity.

When fitting of the function f_{y} (vᵢ, P) set as a physical model and an observed value is performed by using the error function S shown in the equation (2), there is a problem to what degree the value of the error function S should be reduced for the judgment that a high-quality parameter set P can be obtained.

Specifically, as the second problem discussed in the description of the background art, there is a problem that computational expenses for reaching a true minimum value become enormous when the combinatorial optimization method is used as the minimum-value solver. Further, there is another problem that use of the Newton-based solution causes entrapment in local solutions.

Then, when it is judged by some standard that minimization of the error is sufficiently made, it is efficient that the calculation is immediately terminated at that stage and the parameter set P is extracted.

When attention is paid to the error function S shown in the equation (2), assuming that the function f_{y} (vᵢ, P) represents the average value of the characteristic quantities giy with respect to a population of u samples to be observed, it is considered that the equation (2) conforms to χ² distribution. The reason is as follows: assuming that the error factor of the observed value of the characteristic quantity g_{sy} is incidental at each bias point (e.g., vₛ) of the extrinsic factor sets vᵢ, it is considered that the error distribution in the population is a normal distribution, and the characteristic quantity g_{sy} in the equation (2) represents the observed value of the physical property of each sample and the variance σ_{sy}² represents an unbiased estimation value of the variance of the population.

Therefore, utilizing the conformity of the error function S shown in the equation (2) to χ² distribution, it is verified if the function f_{y} (vₛ, P) obtained by calculation using the updated parameter set P reproduces the observed values of the characteristic quantity set gₛ obtained from a plurality of samples, and when it is verified that the function reproduces it, the parameter set P at that time is extracted as one that gives the minimum value of the error function S.

For this verification, a judgment is made on whether the hypothesis that the function f_{y} (vᵢ, P) represents the average value of the population to be observed is rejected or not. Specifically, the judgment on whether the hypothesis is rejected or not is made depending on whether the value of probability obtained by integrating χ² distribution function from 0 to the value of the error function S calculated on the basis of the value of the updated parameter set P falls within a predetermined standard for rejection. When the hypothesis is rejected, update of the parameter set P is performed, instead of adopting the parameter set P at that time. On the other hand, when the hypothesis is not rejected, considering that the function f_{y} (vₛ, P) reproduces the observed values of the characteristic quantity set gₛ, it is judged that the parameter set P at that time has high quality.

More specifically, the verification is performed according to the following procedure. First, the χ² distribution function is expressed by the equation (11):

$${F}_{x} ( S ) = \frac{{( \frac{S}{2} )}^{( \frac{x}{2} - 1 )}}{2 Γ ( \frac{x}{2} )} \cdot exp ( - \frac{S}{2} ) \qquad ( 11 )$$

where Fₓ(S), x and Γ represent χ² distribution function, degree of freedom and gamma function, respectively. Further, the degree of freedom x is calculated by using the number m of bias points of the extrinsic factor sets vᵢ and the number n of parameter sets P, being expressed as x=m−n−1.

Then, by integrating the equation (11) from S=0 to S=S₀ (S₀ is a value of error function S obtained by calculation on the basis of the values of the updated parameter set P) as shown in the left side of the following equation (12), a probability value of χ² distribution function is calculated.

∫₀^{S}^{₀}Fₓ(S)ds<(1−a) (12)

where (1−a) of the right side represents the rejection standard, and as a, values such as 0.01, 0.05 and 0.10 are adopted.

As shown in the equation (12), when the calculated value in the left side becomes smaller than the value in the right side, the hypothesis is not rejected and the parameter set P at that time is adopted as one that gives the minimum value of the error function S. On the other hand, when the calculated value in the left side becomes larger than the value in the right side, the hypothesis is rejected, not adopting the parameter set P at that time, and it is verified that the function f_{y} (vₛ, P) does not reproduce the observed values of the characteristic quantity set gₛ.

Further, when it is verified that the function f_{y} (vₛ, P) obtained by calculation using the updated parameter set P does not reproduce the observed values of the characteristic quantity set gₛ, a judgment is made on whether the parameter set P at that time gives the minimum value of the error function S according to the convergence condition for the minimum-value solver like in the first preferred embodiment.

Then, when it is judged to give the minimum value, the parameter set P at that time is adopted as one that gives the minimum value of the error function S and when it is not judged to give the minimum value, a judgment is made on whether the parameter set P should be updated according to the number of updates like in the first preferred embodiment.

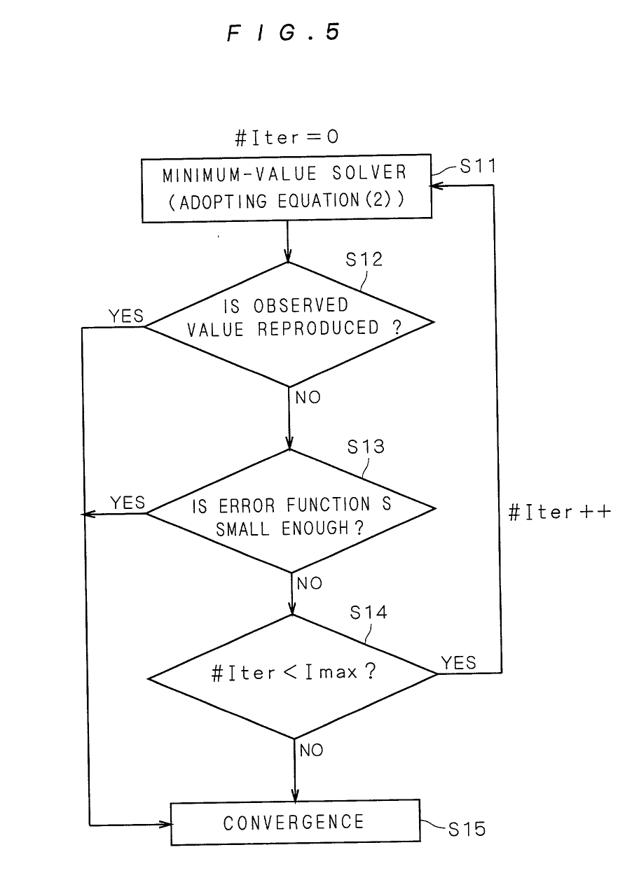

The flowchart of FIG. 5 shows a series of steps as discussed above. Specifically, the step S11 is a step for performing the minimum-value solver such as the combinatorial optimization method or the Newton-based solution, and the step S12 is a step for calculating the probability value of the χ² distribution function and verifying if the function f_{y} (vₛ, P) obtained by calculation using the updated parameter set P reproduces the observed values of the characteristic quantity set gₛ. The step S13 is a step for judging if the convergence condition for the minimum-value solver is satisfied and the step S14 is a step for judging if the parameter set P should be updated according to the number of updates.

When it is verified that the function reproduces the observed values in the step S12 or it is judged that the convergence condition is satisfied in the step S13, considering that the error function S converges, the parameter set P at that time is extracted as one that gives the minimum value of the error function S (step S15). When it is judged that the number of updates #Iter does not exceed the predetermined number of times Imax in the step S14, the parameter set P is updated and the process returns to the step S11, and when it is judged that #Iter exceeds Imax, the parameter set P at that time is extracted as one that gives the minimum value of the error function S (step S15).

In the method of extracting physical model parameters of the second preferred embodiment, since it is verified whether the function f_{y} (vₛ, P) reproduces the observed values by utilizing the conformity of the value of the error function S to χ² distribution function and the parameter set P at that time is extracted as one that gives the minimum value of the error function S when it is verified that the function reproduces the observed values, it is not necessary to repeat the calculation until the value of error function S converges to be considered as minimum and therefore an efficient and quick extraction of the parameter set P can be achieved.

Further, since the process comprises the steps S13 and S14, even when it is verified that the function f_{y} (vₛ, P) does not reproduce the observed values, a subsidiary extraction of the parameter set P can be achieved.

<The Third Preferred Embodiment>

The third preferred embodiment is a variation of the method of extracting physical model parameters in accordance with the second preferred embodiment. Specifically, in the third preferred embodiment, when the number of updates #Iter exceeds the predetermined number of times Imax in the step S14 of the flowchart shown in FIG. 5, the method of minimum-value solver is changed, instead of extracting the parameter set P at that time as one that gives the minimum value of the error function S. Then, using a new minimum-value solver, verification on whether the function f_{y} (vₛ, P) reproduces the observed values, judgment on whether the convergence condition for the minimum-value solver is satisfied and judgment on whether the parameter set P should be updated according to the number of updates are performed again.

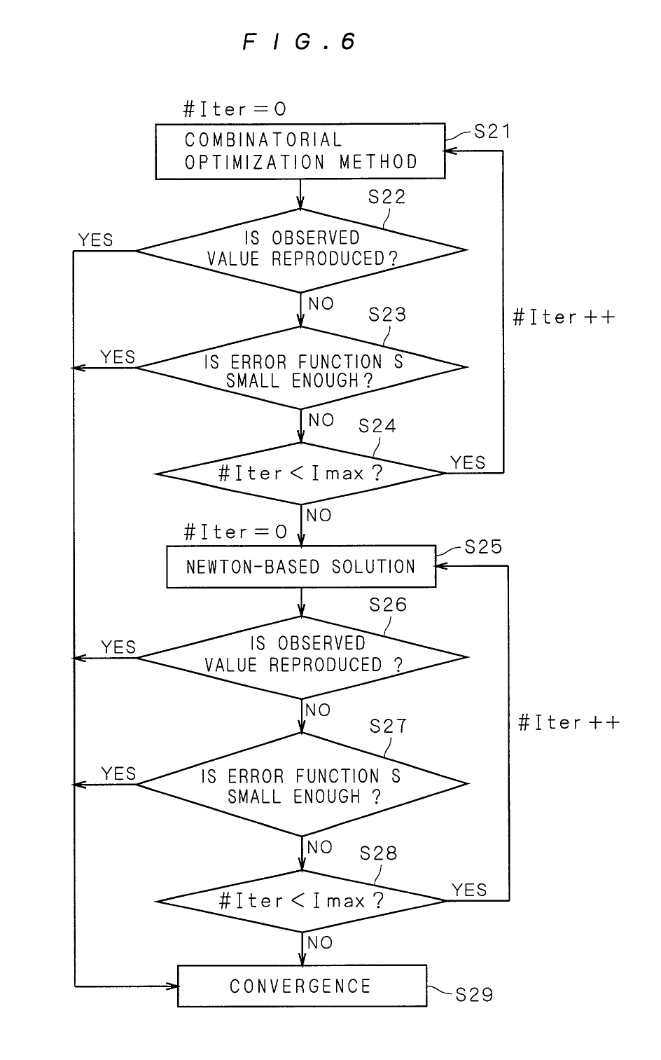

FIG. 6 is a flowchart showing a case, as an example of the third preferred embodiment, where the combinatorial optimization method is adopted as the minimum-value solver first and when the number of updates #Iter exceeds the predetermined number of times Imax, the Newton-based solution is adopted as the minimum-value solver. Specifically, the step S21 is a step for performing the combinatorial optimization method and the step S22 is a step for calculating the probability value of χ² distribution function and verifying if the function f_{y} (vᵢ, P) obtained by calculation using the updated parameter set P reproduces the observed values of the characteristic quantity set gₛ. The step S23 is a step for judging if the convergence condition for the minimum-value solver is satisfied and the step S24 is a step for judging if the parameter set P should be updated according to the number of updates. When it is verified that the function reproduces the observed values in the step S22 or it is judged that the convergence condition is satisfied in the step S23, considering that the error function S converges, the parameter set P at that time is extracted as one that gives the minimum value of the error function S (step S29). When it is judged that the number of updates #Iter does not exceed the predetermined number of times Imax in the step S24, the parameter set P is updated and the process returns to the step S21.

On the other hand, when it is judged that the number of updates #Iter exceeds the predetermined number of times Imax in the step S24, the number of updates #Iter is reset to zero and the minimum-value solver is changed to the Newton-based solution (step S25). Then, the steps S26 to S28 like the steps S22 to S24 are performed.

When it is verified that the function reproduces the observed values in the step S26 or it is judged that the convergence condition is satisfied in the step S27, considering that the error function S converges, the parameter set P at that time is extracted as one that gives the minimum value of the error function S (step S29). When it is judged that the number of updates #Iter does not exceed the predetermined number of times Imax in the step S28, the parameter set P is updated and the process returns to the step S25 and when it is judged that #Iter exceeds Imax, the parameter set P at that time is extracted as one that gives the minimum value of the error function S (step S29).

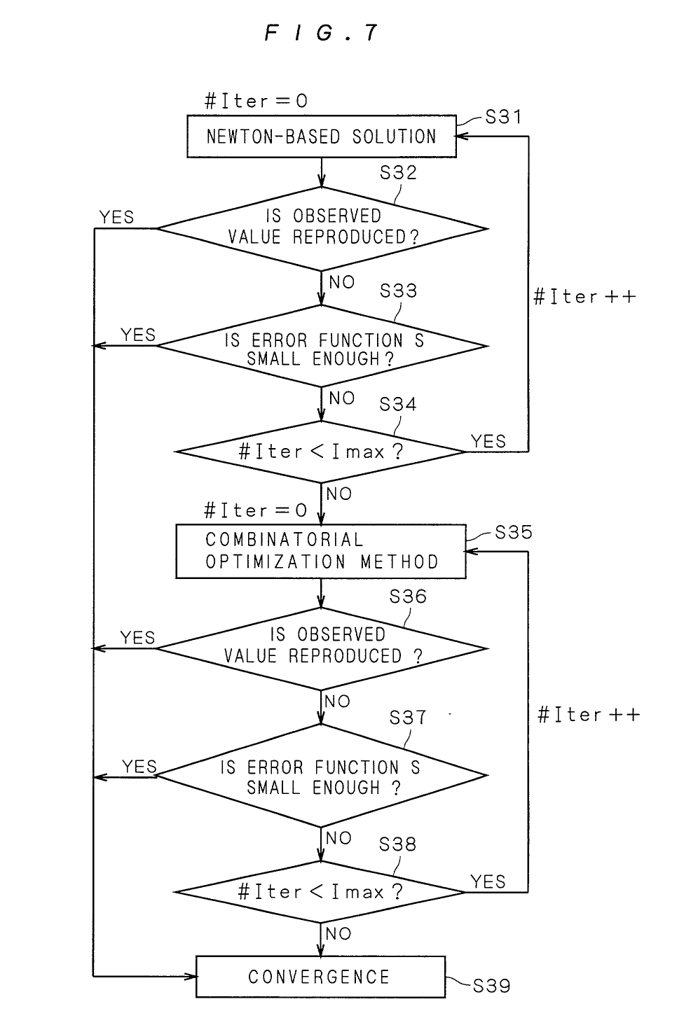

FIG. 7 is a flowchart showing a case, as another example of the third preferred embodiment, where the Newton-based solution is adopted as the minimum-value solver first and when the number of updates #Iter exceeds the predetermined number of times Imax, the combinatorial optimization method is adopted as the minimum-value solver. The steps S31 to S39 in FIG. 7 are the same as the steps in FIG. 6 except that the step S21 for performing the combinatorial optimization method and the step S25 for performing the Newton-based solution are exchanged.

In the case of FIG. 6, since the combinatorial optimization method is performed first, the error function S can be globally approximated to the minimum value to some degree and after that, the local minimum value can be obtained by performing the Newton-based solution.

On the other hand, in the case of FIG. 7, since the Newton-based solution is performed first, the computational expenses are small and high-quality parameter set P can be sometimes obtained in early stage. Then, even if no high-quality parameter set P is obtained by the Newton-based solution, it is possible to thereafter obtain the parameter set P by the combinatorial optimization method.

In the method of extracting physical model parameters of the third preferred embodiment, when it is judged that the number of updates of the parameter set P exceeds the predetermined number of times, the method of minimum-value solver is changed, instead of extracting the parameter set P at that time as one that gives the minimum value of the error function S, and verification on whether the function f_{y} (vₛ, P) reproduces the observed values, judgment on whether the convergence condition for the minimum-value solver is satisfied and judgment on whether the parameter set P should be updated according to the number of updates are performed again. That makes it possible to adopt one of the combinatorial optimization method and the Newton-based solution as the minimum-value solver first and adopt the other one as the minimum-value solver to retry the extraction of the parameter set P when the first method fails the extraction of the parameter set P.

While the invention has been shown and described in detail, the foregoing description is in all aspects illustrative and not restrictive. It is therefore understood that numerous modifications and variations can be devised without departing from the scope of the invention.

What is claimed is:

1. A method of extracting physical model parameters, comprising the steps of:
(a) adopting a physical model for physical properties that provide characteristic quantity sets gᵢ (i=1, 2, . . . , m) each consisting of the first to z-th (z≧2) characteristic quantities g_{iy} (y=1, 2, . . . , z), corresponding to a plurality of extrinsic factor sets vᵢ, respectively, each of which consists of at least one extrinsic factor, said physical model expressing a calculated value of each characteristic quantity set gₛ (s is any one value of i) as a function f_{y} (vₛ, P) of corresponding one extrinsic factor set vₛ and a parameter set P consisting of a plurality of parameters; and
(b) obtaining an error function S by summing values each of which are obtained by dividing the square of the difference between each of said characteristic quantities g_{iy} and corresponding function f_{y} (vᵢ, P) by variance σ_{iy}² of observed values of said characteristic quantities g_{iy} obtained by observing said physical properties of a plurality of samples, for the plural number of extrinsic factor sets and extracting said parameter set P that gives the minimum value of said error function S.

2. The method of extracting physical model parameters according to claim 1, wherein
said step (b) is the step of:
(b-a) extracting said parameter set P that gives the minimum value of said error function S by obtaining said error function S repeatedly with said parameter set P updated, and
said step (b) includes the step of:
(b-1) verifying if said function f_{y} (vₛ, P) obtained by calculation using updated parameter set P reproduces said observed values of each characteristic quantity set gₛ, obtained from said plurality of samples by utilizing conformity of the value of said error function S to χ² distribution and extracting said parameter set P at that time as one that gives the minimum value of said error function S when said function f_{y} (vₛ, P) reproduces the observed values.

3. The method of extracting physical model parameters according to claim 2, wherein
said step (b) is the step of:
obtaining said error function S repeatedly with said parameter set P updated while maintaining a probability Q of increasing the value of said error function S positive.

4. The method of extracting physical model parameters according to claim 3, wherein
said probability Q is obtained on the basis of a predetermined amount which fluctuates monotonously as said parameter set P is updated, and
said predetermined amount contributes to a tendency to decrease said probability Q as said parameter set P is updated.

5. The method of extracting physical model parameters according to claim 2, wherein
said step (b) is the step of:
updating said parameter set P only in such a direction that the error function S decreases monotonously.

6. The method of extracting physical model parameters according to claim 5, wherein
Gauss-Newton method is adopted in said step (b).

7. The method of extracting physical model parameters according to claim 5, wherein
Levenberg-Marquardt method is adopted in said step (b).

8. The method of extracting physical model parameters according to claim 2, wherein
said step (b) further includes the steps of:
(b-2) judging if the value of said error function S obtained with said parameter set P updated is considered as the minimum value when said function f_{y} (vₛ, P) does not reproduce said observed values of said characteristic quantity set gₛ, obtained from said plurality of samples in said step (b-1) and extracting said parameter set P at that time as one that gives the minimum value of said error function S when the value of said error function S is considered as the minimum value; and
(b-3) judging if the number of updates exceeds a predetermined number of times when the value of said error function S is not considered as the minimum value in said step (b-2) and extracting said parameter set P at that time as one that gives the minimum value of said error function S when the number of updates exceeds said predetermined number of times or obtaining the value of said error function S with said parameter set P updated to go back to said step (b-1) when the number of updates does not exceed said predetermined number of times.

9. The method of extracting physical model parameters according to claim 8, wherein
the method used in said step (b-a) of extracting said parameter set P that gives the minimum value of said error function S is changed to execute said steps (b-1) to (b-3) again, instead of extracting said parameter set P at that time as one that gives the minimum value of said error function S, when it is judged that the number of updates exceeds said predetermined number of times in said step (b-3).

10. A computer-readable storage medium for storing a program that causes a computer to execute a method of extracting physical model parameters independently or in combination with a program previously stored in said computer,
wherein said method of extracting physical model parameters comprises the steps of:
(a) adopting a physical model for physical properties that provide characteristic quantity sets gᵢ (i=1, 2, . . . , m) each consisting of the first to z-th (z≧2) characteristic quantities g_{iy} (y=1, 2, . . . , z), corresponding to a plurality of extrinsic factor sets vᵢ, respectively, each of which consists of at least one extrinsic factor, said physical model expressing a calculated value of each characteristic quantity set gₛ (s is any one value of i) as a function f_{y} (vₛ, P) of corresponding one extrinsic factor set vₛ and a parameter set P consisting of a plurality of parameters; and
(b) obtaining an error function S by summing values each of which are obtained by dividing the square of the difference between each of said characteristic quantities g_{iy} and corresponding function f_{y} (vᵢ, P) by variance σ_{iy}² of observed values of said characteristic quantities g_{iy} obtained by observing said physical properties of a plurality of samples, for the plural number of extrinsic factor sets and extracting said parameter set P that gives the minimum value of said error function S.

11. The computer-readable storage medium according to claim 10, wherein
said step (b) in the method of extracting physical model parameters is the step of:
(b-a) extracting said parameter set P that gives the minimum value of said error function S by obtaining said error function S repeatedly with said parameter set P updated, and
said step (b) in the method of extracting physical model parameters includes the step of:
(b-1) verifying if said function f_{y} (vₛ, P) obtained by calculation using updated parameter set P reproduces said observed values of each characteristic quantity set gₛ obtained from said plurality of samples by utilizing conformity of the value of said error function S to χ² distribution and extracting said parameter set P at that time as one that gives the minimum value of said error function S when said function f_{y} (vₛ, P) reproduces the observed values.

12. The computer-readable storage medium according to claim 11, wherein
said step (b) in the method of extracting physical model parameters is the step of:
obtaining said error function S repeatedly with said parameter set P updated while maintaining a probability Q of increasing the value of said error function S positive.

13. The computer-readable storage medium according to claim 11, wherein
said step (b) in the method of extracting physical model parameters is the step of:
updating said parameter set P only in such a direction that the error function S decreases monotonously.

14. The computer-readable storage medium according to claim 11, wherein
said step (b) in the method of extracting physical model parameters further includes the steps of:
(b-2) judging if the value of said error function S obtained with said parameter set P updated is considered as the minimum value when said function f_{y} (vₛ, P) does not reproduce said observed values of said characteristic quantity set gₛ obtained from said plurality of samples in said step (b-1) and extracting said parameter set P at that time as one that gives the minimum value of said error function S when the value of said error function S is considered as the minimum value; and
(b-3) judging if the number of updates exceeds a predetermined number of times when the value of said error function S is not considered as the minimum value in said step (b-2) and extracting said parameter set P at that time as one that gives the minimum value of said error function S when the number of updates exceeds said predetermined number of times or obtaining the value of said error function S with said parameter set P updated to go back to said step (b-1) when the number of updates does not exceed said predetermined number of times.

15. The computer-readable storage medium according to claim 14, wherein
the method used in said step (b-a) of extracting said parameter set P that gives the minimum value of said error function S is changed to execute said steps (b-1) to (b-3) of the method of extracting physical model parameters again, instead of extracting said parameter set P at that time as one that gives the minimum value of said error function S, when it is judged that the number of updates exceeds said predetermined number of times in said step (b-3) of the method of extracting physical model parameters.

16. A method of manufacturing a non-linear element for manufacturing a non-linear element by performing:
a characteristic simulation which adopts device modeling using a method of extracting physical model parameters; and
a physical process on the basis of said characteristic simulation,
wherein said method of extracting physical model parameters comprising the steps of:
(a) adopting a physical model for physical properties that provide characteristic quantity sets gᵢ (i=1, 2, . . . , m) each consisting of the first to z-th (z≧2) characteristic quantities g_{iy} (y=1, 2, . . . , z), corresponding to a plurality of extrinsic factor sets vᵢ, respectively, each of which consists of at least one extrinsic factor, said physical model expressing a calculated value of each characteristic quantity set gₛ (s is any one value of i) as a function f_{y} (vₛ, P) of corresponding one extrinsic factor set vₛ and a parameter set P consisting of a plurality of parameters; and
(b) obtaining an error function S by summing values each of which are obtained by dividing the square of the difference between each of said characteristic quantities g_{iy} and corresponding function f_{y} (vᵢ, P) by variance σ_{iy}² of observed values of said characteristic quantities g_{iy} obtained by observing said physical properties of a plurality of samples, for the plural number of extrinsic factor sets and extracting said parameter set P that gives the minimum value of said error function S.

17. The method of manufacturing a non-linear element according to claim 16, wherein
said step (b) in the method of extracting physical model parameters is the step of:
(b-a) extracting said parameter set P that gives the minimum value of said error function S by obtaining said error function S repeatedly with said parameter set P updated, and
said step (b) in the method of extracting physical model parameters includes the step of:
(b-1) verifying if said function f_{y} (vₛ, P) obtained by calculation using updated parameter set P reproduces said observed values of each characteristic quantity set gₛ obtained from said plurality of samples by utilizing conformity of the value of said error function S to χ² distribution and extracting said parameter set P at that time as one that gives the minimum value of said error function S when said function f_{y} (vᵢ, P) reproduces the observed values.

18. The method of manufacturing a non-linear element according to claim 17, wherein
said step (b) in the method of extracting physical model parameters further includes the step of:
(b-2) judging if the value of said error function S obtained with said parameter set P updated is considered as the minimum value when said function f_{y} (vₛ, P) does not reproduce said observed values of said characteristic quantity set gₛ obtained from said plurality of samples in said step (b-1) and extracting said parameter set P at that time as one that gives the minimum value of said error function S when the value of said error function S is considered as the minimum value; and
(b-3) judging if the number of updates exceeds a predetermined number of times when the value of said error function S is not considered as the minimum value in said step (b-2) and extracting said parameter set P at that time as one that gives the minimum value of said error function S when the number of updates exceeds said predetermined number of times or obtaining the value of said error function S with said parameter set P updated to go back to said step (b-1) when the number of updates does not exceed said predetermined number of times.

19. The method of manufacturing a non-linear element according to claim 18, wherein
the method used in said step (b-a) of extracting said parameter set P that gives the minimum value of said error function S is changed to execute said steps (b-1) to (b-3) of the method of extracting physical model parameters again, instead of extracting said parameter set P at that time as one that gives the minimum value of said error function S, when it is judged that the number of updates exceeds said predetermined number of times in said step (b-3) of the method of extracting physical model parameters.
